(19) United States
(12) Patent Application Publication
(10) Pub. No.: US 2015/0075586 A1
(43) Pub. Date: Mar. 19, 2015

(54) SOLAR CELL MODULE

(71) Applicant: LG INNOTEK CO., LTD., Seoul (KR)

(72) Inventor: Min Jung Shin, Seoul (KR)

(73) Assignee: LG INNOTEK CO., LTD., Seoul (KR)

(21) Appl. No.: 14/383,086

(22) PCT Filed: Mar. 5, 2013
(86) PCT No.: PCT/KR2013/001780

§ 371 Date: Sep. 4, 2014

(30) Foreign Application Priority Data
Mar. 5, 2012 (KR) 10-2012-0022233

(51) Int. Cl. H01L 31/048

(52) U.S. Cl. CPC H01L 31/048; H01L 31/0481
USPC 136/251

(57) ABSTRACT

Disclosed is a solar cell module. The solar cell module includes a solar cell panel, and a protective part surrounding the solar cell panel.

### TECHNICAL FIELD

The embodiment relates to a solar cell module.

### BACKGROUND ART

A solar cell module to convert light energy into electrical energy through photoelectric conversion effect has been extensively known as a device to obtain non-pollution energy contributing to the conservation of global environment.

As the photoelectric conversion effect of a solar cell is improved, a great number of solar cell systems having a solar cell module are installed even for home use.

In order to output power generated from the solar cell module including solar cells that generate power from the light of the sun to the outside, conductors acting as positive and negative electrodes are provided in the solar cell module, and terminals of the conductors, which serve as connectors connected to a cable of outputting current to the outside, are withdrawn out of a photovoltaic module.

However, since moisture is infiltrated through the edge in the case of a solar cell module having a typical structure, the reliability of the solar cell module may be generally degraded. In addition, the weight of the solar cell module may be increased due to a protective glass to protect a solar cell panel.

### DISCLOSURE OF INVENTION

### Technical Problem

The embodiment provides a solar cell module representing improved reliability.

### Solution to Problem

According to the embodiment, there is provided a solar cell module including a solar cell panel, and a protective part surrounding the solar cell panel.

### Advantageous Effects of Invention

The solar cell module according to the embodiment includes the protective part. The protective part encapsulates the entire surface of the solar cell panel, thereby preventing moisture from being infiltrated into the solar cell panel. Accordingly, the reliability of the solar cell module can be improved.

In addition, since the protective glass on the existing solar cell panel and an EVA sheet used to bond the protective glass with the solar cell panel can be omitted due to the protective part, the solar cell module can be simplified. In other words, the weight of the solar cell module can be reduced.

### BRIEF DESCRIPTION OF DRAWINGS

FIG. 1 is an exploded perspective view showing a solar cell module according to an embodiment.

FIG. 2 is a sectional view taken along line A-A′ of FIG. 1.

### MODE FOR THE INVENTION

In the following description of the embodiments, it will be understood that, when a layer (film), a region, a pattern or a structure is referred to as being “on” or “under” another layer (film), region, pattern or structure, it can be “directly” or “indirectly” on the other layer (film), region, pattern or structure, or one or more intervening layers may also be present. Such a position of each layer described with reference to the drawings.

The thickness and size of each layer (film), region, pattern or structure shown in the drawings may be exaggerated, omitted or schematically drawn for the purpose of convenience or clarity. In addition, the size of each layer (film), region, pattern or structure does not utterly reflect an actual size.

Hereinafter, the embodiment will be described in detail with reference to accompanying drawings.

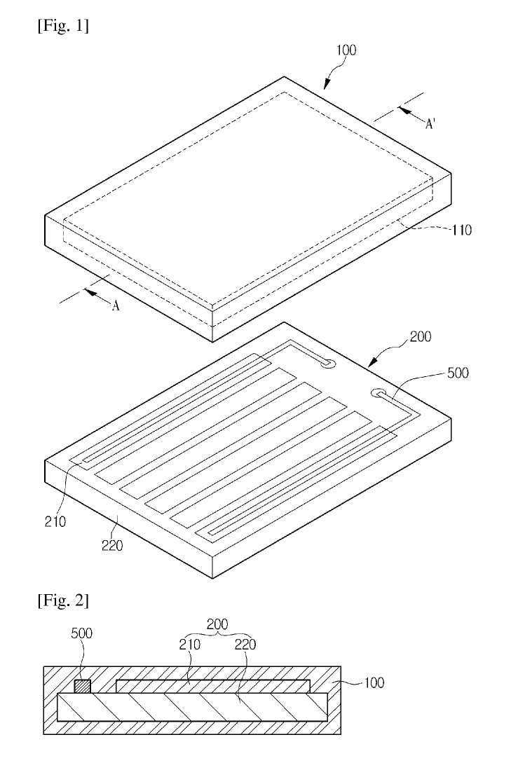

Hereinafter, a solar cell module according to the embodiment will be described in detail with reference to FIGS. 1 and 2. FIG. 1 is an exploded perspective view showing a solar cell module according to an embodiment. FIG. 2 is a sectional view taken along line A-A′ of FIG. 1.

Referring to FIGS. 1 and 2, the solar cell module according to the embodiment includes a protective part 100 and a solar cell panel 200.

The protective part 100 surrounds the solar cell panel 200. The protective part 100 surrounds the entire surface of the solar cell panel 200. Accordingly, the protective part 100 may be placed on a top surface, a bottom surface, and a lateral side of the solar cell panel 200.

The protective part 100 includes a receiving part 110. The receiving part 110 is placed inside the protective part 100. The receiving part 110 may be a groove to receive the solar cell panel 200.

The light receiving part 110 may receive the solar cell panel 200. Accordingly, the light receiving part 110 may have the size equal to the size of the solar cell panel 200.

The protective part 100 may include plastic. The plastic has high strength and superior waterproof, so that the solar cell panel 200 can be protected. In addition, the plastic is transparent, so that the transmittance of the light transmitted to the solar cell panel 200 can be improved. For instance, the protective part 100 may include polycarbonate (PC). However, the embodiment is not limited thereto, but the protective part 100 may include various materials that are transparent, have superior waterproof, and great impact strength.

The protective part 100 may be packaged by surrounding and pressing the entire surface of the solar cell panel 200. In this case, before processing the protective part 100, the protective part 100 must be sufficiently dried.

The protective part 100 encapsulates the entire surface of the solar cell panel 200, thereby preventing moisture from being infiltrated into the solar cell panel 200. Accordingly, the reliability of the solar cell module can be improved.

In addition, since the protective glass on the existing solar cell panel 200, an EVA sheet used to bond the protective glass with the solar cell panel 200, and a back sheet provided on the back side of the solar cell panel 200 can be omitted due to the protective part 100, the solar cell module can be simplified. In other words, the weight of the solar cell module can be reduced.

The solar cell panel 200 is provided inside the protective part 100. In detail, the solar cell panel 200 is placed in the receiving part 110. The solar cell panel 200 may directly make contact with the protective part 100.

The solar cell panel 200 has the shape of a plate. The solar cell panel 200 includes a plurality of solar cells 210 and a lower substrate 220 to support the solar cells 210.

For instance, the solar cells 210 may include a CIGS-based solar cell, a silicon-based solar cell, a dye-sensitized solar cell, a group II-VI compound semiconductor solar cell, or a group III-V compound semiconductor solar cell.

In addition, the solar cells 210 may be disposed on a transparent substrate such as a glass substrate.

The solar cells 210 may be arranged in the shape of a stripe. In addition, the solar cells 210 may be arranged in various shapes including the shape of a matrix.

A bus bar 500 is disposed on the solar cell panel 200. The bus bar 500 makes contact with the top surfaces of two solar cells 210 while being electrically connected to the solar cells 210.

For instance, the bus bar 500 includes first and second bus bars.

The first bus bar makes contact with the top surface of one outermost solar cell 210, and the second bus bar makes contact with the top surface of an opposite outermost solar cell 210.

The bus bar 500 is a conductor. The bus bar 500 may include copper (Cu).

Although not shown, an additional frame to receive the protective part 100 and the solar cell panel 200 may be further included. A building integrated photovoltaic system (BIPV) module can be realized as the substitute for transparent glass of a building by using the additional frame.

However, the embodiment is not limited thereto. In other words, the BIPV module can be realized by using only the protective part without the frame. Accordingly, the solar cell module can be more simplified.

The features, structures, and effects described in the above embodiments are included in at least one embodiment of the present invention, and are not necessarily limited to only one embodiment. Moreover, the features, structures, and effects described in the embodiments may also be combined or modified to be carried out in other embodiments by those skilled in the art to which the embodiments pertain. Thus, the contents related to the combination and modification shall be construed to be included in the scope of the present invention.

Further, although the embodiments have been mainly described until now, they are just exemplary and do not limit the present invention. Thus, those skilled in the art to which the present invention pertains will know that various modifications and applications which have not been exemplified may be carried out within a range which does not deviate from the essential characteristics of the embodiments. For instance, the constituent elements described in detail in the exemplary embodiments can be modified to be carried out. Further, the differences related to such modifications and applications shall be construed to be included in the scope of the present invention specified in the attached claims.

1. A solar cell module comprising:
a solar cell panel; and
a protective part surrounding the solar cell panel.

2. The solar cell module of claim 1, wherein the protective part surrounds an entire surface of the solar cell panel.

3. The solar cell module of claim 1, wherein the solar cell panel is placed in the protective part.

4. The solar cell module of claim 1, wherein the protective part includes a receiving part to receive the solar cell panel.

5. The solar cell module of claim 1, wherein the solar cell panel directly makes contact with the protective part.

6. The solar cell module of claim 1, wherein the protective part includes plastic.

7. The solar cell module of claim 1, wherein the protective part includes polycarbonate (PC).

8. The solar cell module of claim 1, wherein the protective part is disposed on a top surface, a bottom surface, and a lateral side of the solar cell panel.

9. The solar cell module of claim 4, wherein the receiving part has a size corresponding to a size of the solar cell panel.

10. The solar cell module of claim 1, wherein the protective part include transparent materials.

11. The solar cell module of claim 2, wherein the protective part packaged pressing the entire surface of the solar cell panel.
